(19) United States
(12) Patent Application Publication
(10) Pub. No.: US 2011/0171585 A1
(43) Pub. Date: Jul. 14, 2011

(54) Photolithography Method

(75) Inventor: Sejin Park, Shanghai (CN)

(73) Assignee: SEMICONDUCTOR MANUFACTURING INTERNATIONAL (Shanghai) Corporation, Shanghai (CN)

(21) Appl. No.: 12/780,728

(22) Filed: May 14, 2010

(30) Foreign Application Priority Data
Jan. 8, 2010 (CN) 201010022586.3

(51) Int. Cl. G03F 7/20

(52) U.S. Cl. 430/323; 430/322; 430/326

(57) ABSTRACT

A photolithography method is provided which includes: arranging a layout topography in a first mask and a second mask in such a way that at least a layout pattern of the layout topography is defined by an overlap area. The overlap area is formed when at least a first pattern of the first mask and at least a second pattern of the second mask are projected on a common surface and are overlapped to each other. Critical dimensions of the first mask and the second mask are larger than a resolution of a photolithography machine for preventing from bridging.

### CROSS REFERENCE TO RELATED APPLICATIONS

The present application claims the priority of Chinese Patent Application No. 201010022586.3, entitled “Photolithography Method”, and filed Jan. 8, 2010, the entire disclosure of which is incorporated herein by reference.

### BACKGROUND OF THE INVENTION

1. Field of the Invention

The present invention relates to photolithography, and particularly relates to a photolithography method used for semiconductor devices.

2. Description of Prior Art

With rapid development of integrated circuit design, a mask for photolithography increasingly has reduced size and enhanced optical proximity effect. When exposure beams extend through a mask and are projected to a photoresist layer on a wafer, patterns formed on the photoresist layer tend to be deformed and deflected with respect to patterns of the mask, which will have adverse influence upon formation of patterns of a layout topography on the wafer by means of photolithography.

Referring to FIG. 13, spacing between patterns of a mask 110 is so small that during exposure of the mask 110, exposure beams through adjacent patterns are overlapped or counteracted during a layout topography 120 is produced by a conventional photolithography process. In this layout topography 120, patterns occur at improper positions, thereby producing bridging, or otherwise no desired patterns are exposed properly at appropriate positions.

A mask is generally provided according to a layout topography. If critical dimensions of a layout topography are smaller than a resolution of a photolithography machine, a conventional twice exposures process is generally employed to attain the layout topography. Formation of a layout topography by the conventional twice exposures process is illustrated below as an example.

With reference to FIG. 14, spacing d between patterns of a layout topography 100 is smaller than a resolution of a photolithography machine. The layout topography 100 is arranged in at least two masks, which are designated as a first mask 101 and a second mask 102 respectively. Both critical dimensions d1 of the first mask 101 and critical dimensions d2 of the second mask 102 are larger than the resolution of the photolithography machine. Referring to FIGS. 15A-15C, the first mask 101 is transferred to a first photoresist layer 201 on a wafer 200 after exposure and development. The first photoresist layer 201 is etched to transfer patterns of the first mask 101 to the wafer 200. A second photoresist layer 202 is formed on the wafer 200 by spin coating, as shown in FIG. 15C. Referring to FIG. 16, the second mask 102 is transferred to the second photoresist layer 202 on the wafer 200 after exposure and development. The second photoresist layer 202 is etched to obtain the layout topography on the wafer 200 and then is removed, as shown in FIG. 17.

In accordance with the conventional twice photolithography process, multiple layout patterns of a layout topography are divided into two groups with spacing therebetween. The two groups of layout patterns are arranged in two masks. Consequently, spacing between two adjacent patterns of the masks is enlarged substantially by twice. The masks are respectively exposed, developed and etched in sequence in order to preclude from bridging. However, when critical dimensions of the layout patterns of a layout topography decrease significantly, and correspondingly critical dimensions of patterns of the masks decrease significantly, especially in a manufacturing process node of less than 32 nm, the layout topography on the wafer can not be achieved properly by the conventional twice photolithography process. Therefore, an improved photolithography method is desired to produce layout patterns with very small critical dimensions, thereby meeting requirements of the layout topography with tendency of miniature.

### SUMMARY OF THE INVENTION

An object of the present invention is to provide a photolithography method for producing layout patterns with very small critical dimensions and preventing from bridging.

To achieve the object, the photolithography method according to the present invention comprises: arranging a layout topography in a first mask and a second mask in such a way that at least a layout pattern of the layout topography is defined by an overlap area, the overlap area being formed when at least a first pattern of the first mask and at least a second pattern of the second mask are projected on a common surface and are overlapped to each other; providing a wafer which includes at least an etch layer and at least a hard mask on the etch layer; transferring the at least a first pattern of the first mask to the hard mask layer; and forming a second photoresist layer on the hard mask layer and the etch layer, transferring the at least a second pattern of the second mask to the second photoresist layer, and transferring the overlap area to the etch layer according to the hard mask layer and the second photoresist layer for forming the at least a layout pattern of the layout topography on the etch layer.

Critical dimensions of the at least a first mask and the at least a second mask are larger than a resolution of a photolithography machine.

In the step of transferring the at least a first pattern of the first mask to the hard mask layer, a part of the first photoresist layer is exposed to form a first exposed part, the first exposed part corresponding to the at least a first pattern of the first mask.

In the step of transferring the overlap area to the etch layer, a part of the etch layer is exposed to form a second exposed part, the second exposed part corresponding to the overlap area.

By the photolithography method of present invention, the layout patterns with critical dimensions smaller than a resolution of a photolithography machine are obtained. The layout patterns are arranged in at least two masks. The at least two masks are projected on a common surface and are overlapped to each other to define an overlap area to produce the layout patterns. Thus critical dimensions of the masks are enlarged beyond a resolution of a photolithography machine. In this manner, bridging is prevented, and hence yield rate is raised.

### BRIEF DESCRIPTION OF THE DRAWINGS

FIG. 1 is a flow chart of a photolithography method according to the present invention.

FIG. 2 schematically shows a layout topography being defined by a first pattern of a first mask and a second pattern of a second mask according to an embodiment of a step S1 in FIG. 1.

FIG. 3 schematically shows a layout topography being defined by a first pattern of a first mask and multiple second patterns of a second mask according to an alternative embodiment of the step S1 in FIG. 1.

FIG. 4 is a flow chart of a step S2 of the photolithography method in FIG. 1.

FIG. 5 is a flow chart of a step S3 of the photolithography method in FIG. 1.

FIGS. 6-8 are schematically cross-sectional views illustrating the step S3 of FIG. 1 step by step.

FIG. 9 is a flow chart of a step S4 of the photolithography method in FIG. 1.

FIGS. 10-12 are schematically cross-sectional views illustrating the step S4 of FIG. 1 step by step.

FIG. 13 shows a mask, and a layout topography obtained on a wafer according to the mask by a conventional photolithography process, wherein bridging occurs in the layout topography.

FIG. 14 schematically illustrates a layout topography being divided into two groups and being respectively arranged in two masks according to a conventional twice photolithography process.

FIGS. 15A-15C show a first mask being transferred to a wafer according to the conventional twice photolithography process.

FIG. 16 shows a second mask being transferred to the wafer according to the conventional twice photolithography process

FIG. 17 shows a layout topography being obtained on the wafer according to the conventional twice photolithography process

### DETAILED DESCRIPTION OF THE EMBODIMENTS

In accordance with a photolithography method of the present invention, a layout topography, which has layout patterns with critical dimensions smaller than a resolution of a photolithography machine, is arranged in at least two masks. The at least two masks are projected to a common surface and are overlapped to each other, forming an overlap area in the common surface. The overlap area exactly defines the layout patterns of the layout topography. The photolithography method of present invention is adapted for fabrication of the mask and manufacturing of chips. By means of the photolithography method, the layout patterns with critical dimensions smaller than a resolution of a photolithography machine are obtained without bridging, and hence yield rate is improved.

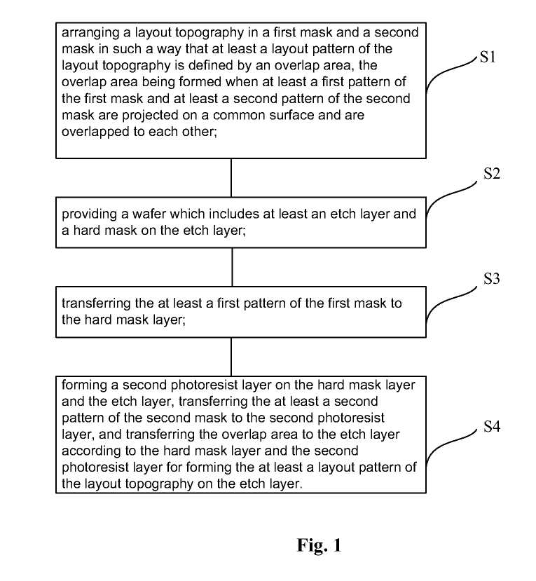

With reference to FIG. 1, the photolithography method of the present invention comprises the following steps:

Step S1, arranging a layout topography in a first mask and a second mask in such a way that at least a layout pattern of the layout topography is defined by an overlap area, the overlap area being formed when at least a first pattern of the first mask and at least a second pattern of the second mask are projected on a common surface and are overlapped to each other;

Step S2, providing a wafer which includes at least an etch layer and at least a hard mask on the etch layer;

Step S3, transferring the at least a first pattern of the first mask to the hard mask layer;

Step S4, forming a second photoresist layer on the hard mask layer and the etch layer, transferring the at least a second pattern of the second mask to the second photoresist layer, and transferring the overlap area to the etch layer according to the hard mask layer and the second photoresist layer for forming the at least a layout pattern of the layout topography on the etch layer.

According to the photolithography method of the present invention, the at least a first pattern is transferred to the hard mask layer, and the at least a second pattern is transferred to the second photoresist layer. Finally, the overlap area, which is formed when at least a first pattern of the first mask and at least a second pattern of the second mask are projected on a common surface and are overlapped to each other, is transferred to the wafer. The at least a first pattern and the at least a second pattern have critical dimensions substantially beyond a resolution of a photolithography machine.

The present invention is further described in combination with detailed embodiments and accompanying drawings.

In the step S1, according to a resolution of a photolithography machine, the layout topography is arranged in at least two masks, for instance a first mask and a second mask. Critical dimensions of the first mask and the second mask are both larger than the resolution of the photolithography machine. The critical dimensions of the first mask comprise critical dimensions of the at least first patterns. The critical dimensions of the second mask comprise critical dimensions of the at least second patterns. When at least a first pattern of the first mask and at least a second pattern of the second mask are projected to a common surface and are overlapped to each other, an overlap area is formed in the common surface for defining the layout topography. In this manner, layout patterns of the layout topography can be retrieved unambiguously on the wafer even the layout patterns are smaller than the resolution of the photolithography machine.

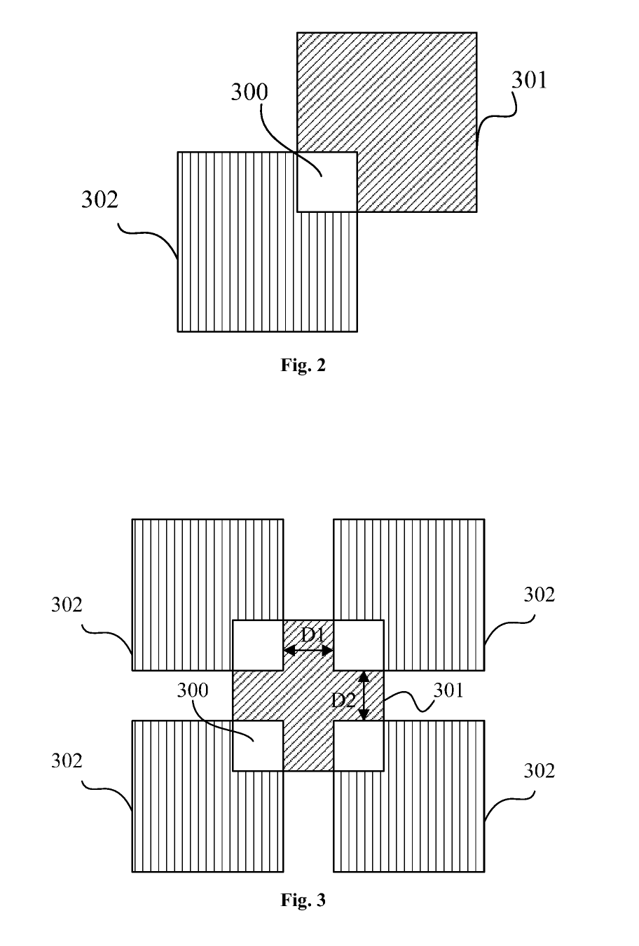

In one embodiment, referring to FIG. 2, a layout topography is arranged in the first mask and the second mask. A first pattern 301 of the first mask and a second pattern 302 of the second mask are overlapped to form an overlap area. The overlap area defines at least a layout pattern 300 of the layout topography. Critical dimensions of the first pattern 301 and the second pattern 302 are both larger than the resolution of the photolithography machine.

In an alternative embodiment, referring to FIG. 3, a layout topography is arranged in a first mask and a second mask. A first pattern 301 of the first mask is overlapped with a plurality of second patterns 302 of the second mask to form an overlap area. The overlap area defines a plurality of layout patterns 300 of the layout topography. A transverse length of the first pattern 301 equals to a sum of transverse lengths of the layout patterns 300 in a transverse line and transverse spacing D1 between the layout patterns 300. A longitudinal length of the first pattern 301 equals to a sum of longitudinal lengths of the layout patterns 300 in a longitudinal line and longitudinal spacing D2 between the layout patterns 300. Even if critical dimensions of the layout patterns 300 are smaller than the resolution of the photolithography machine, critical dimensions of the first patterns 301 and the second patterns 302 exceed the resolution of the photolithography machine, thereby effectively preventing from bridging in the layout topography formed on the wafer.

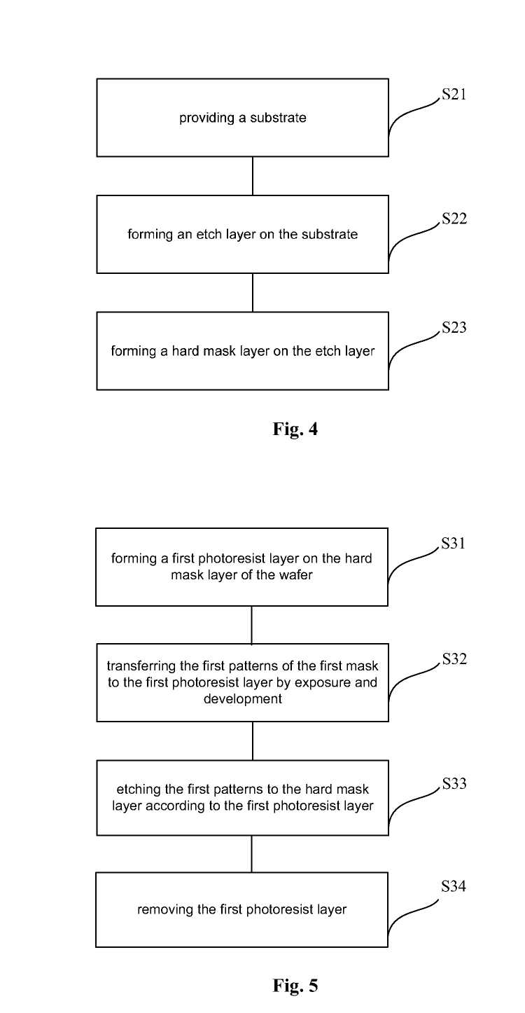

In the step S2, according to one embodiment of the present invention, the wafer includes a substrate, an etch layer on the substrate, and a hard mask layer on the etch layer. Alternatively, the hard mask layer has one part on the substrate, and the other part on the etch layer. Referring to FIG. 4, in one embodiment, the step S2 comprises the following steps.

Step S21, providing a substrate. The substrate is preferably a monocrystalline silicon substrate.

Step 22, forming an etch layer on the substrate. Preferably, the etch layer is formed of silicon dioxide (SiO2) or Tetraethyl orthosilicate (LPTEOS). The etch layer is formed by any process of growing oxidation layer, for instance, growing an oxidation layer on the substrate, or alternatively, oxidizing a surface of the substrate to form an oxidation layer on the surface of the substrate.

Step S23, forming a hard mask layer on the etch layer. The hard mask layer is formed of Silicon Oxynitride (SiON). As an example, the Silicon Oxynitride layer is deposited on the silicon dioxide layer by chemical vapor deposition.

The step S2 further comprises a step of cleaning a wafer. According to one embodiment of the present invention, the step of cleaning a wafer comprises: heating with concentrated sulfuric acid to clean a surface of the wafer, washing by ionic water, and drying to make the surface of the wafer dry for attaching the photoresist layer thereto reliably.

Referring to FIG. 5, the step S3 comprises a step S31 for forming a first photoresist layer on the hard mask layer of the wafer, a step S32 for transferring the first patterns of the first mask to the first photoresist layer by exposure and development, a step S33 for transferring the first patterns to the hard mask layer according to the first photoresist layer by etching, and a step S34 for removing the first photoresist layer.

In the step S31, the first photoresist layer is coated on the hard mask layer. In one embodiment, the first photoresist layer is made of positive photoresist, for example Polymethylmethacrylate (PMMA) or DQN. DQN may be employed to form the first photoresist layer for exposure of beams. The basic material of the first photoresist layer is concentrated phenolic resin polymer. In another embodiment, the first photoresist layer is made of negative photoresist, for example Kodak KTFR. The step S31 further comprises pre-drying the wafer coated with the first photoresist layer for volatilizing solvent therein, for example, pre-drying the wafer for 5-10 minutes at the temperature ranged of 80-110 degrees centigrade.

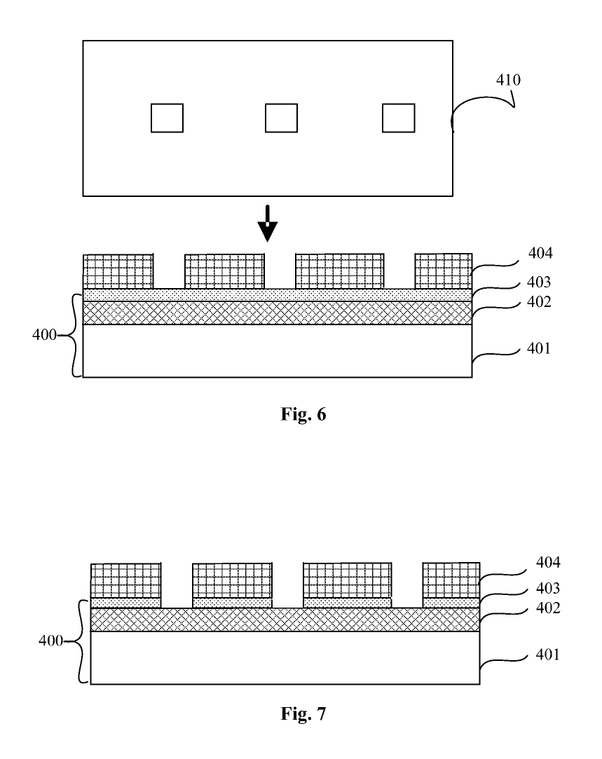

In one embodiment of the present invention, with reference to FIG. 6, the wafer 400 comprises a substrate 401, an etch layer 402 on the substrate 401, and a hard mask layer 403 on the etch layer 402. A first photoresist layer 404 is coated on the hard mask layer 403. The first patterns of the first mask 410 are transferred to the first photoresist layer 404 by exposure and development. Preferably, the wafer 400 is irradiated or radiated with exposure beams according to the first mask 410, such as ultraviolet light, electronic beam, ionic beam, X radiation beams or the like. Then the wafer 400 is developed with a developer. In this embodiment, the first photoresist layer 404 is formed of positive photoresist, the developer is medium alkaline solution, for instance potassium hydroxide (KOH), tetramethyl ammonium hydroxide (TMAH), ketone, or acetazolamide. After developing, a part of the first photoresist layer 404 is exposed to form a first exposed part. The first exposed part corresponds to the first patterns of the first mask 410. In an alternative embodiment, the first photoresist layer 404 is formed of negative photoresist, and the developer is dimethylbenzene.

Referring to FIG. 7, in the step S33, the hard mask layer 403 is etched according to the first photoresist layer 404. The first patterns of the first mask 410 are transferred to the first photoresist layer 404 by exposure and development in the step S32. Consequently, the first patterns of the first mask 410 are transferred to the hard mask layer 403. The hard mask layer 403 is etched by plasma dry etching. The gas for etching is a mixture of Trifluoromethane (CHF3) and Argon (Ar) with volume ratio of 1:3 to 1:0.3.

Referring to FIG. 8, the first photoresist layer 404 is removed in the step S34 by, exemplarily, normal wet or dry photoresist removal methods, for instance, heating with concentrated sulfuric acid, ashing and removing the photoresist, and washing with water.

Referring to FIG. 9, the step S4 comprises the following steps.

Step S41, forming a second photoresist layer on the hard mask layer and the etch layer;

Step S42, transferring the second patterns of the second mask to the second photoresist layer by exposure and development;

Step 43, transferring the overlap area to the wafer according to the second photoresist layer and the hard mask layer by etching.

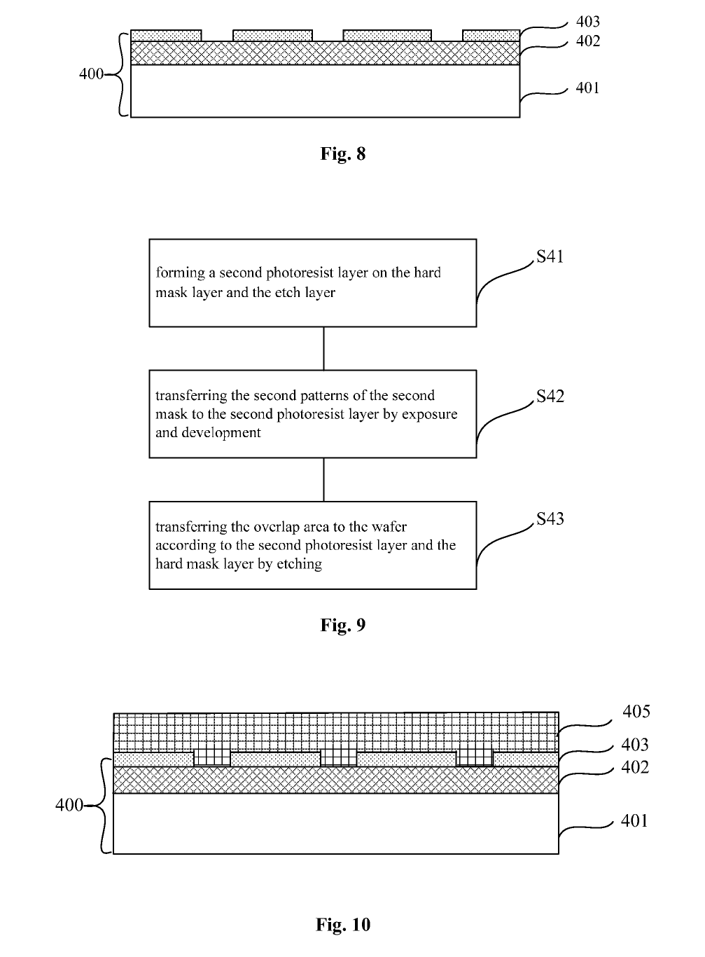

Referring to FIG. 10, a second photoresist layer 405 is coated on the hard mask layer 403 and the etch layer 402. In a preferred embodiment, the wafer 400 with the second photoresist layer 405 is pre-dried. The second photoresist layer 405 is formed of positive photoresist, for instance Polymethylmethacrylate (PMMA) or DQN, or alternative, is formed of negative photoresist, for instance Kodak KTFR.

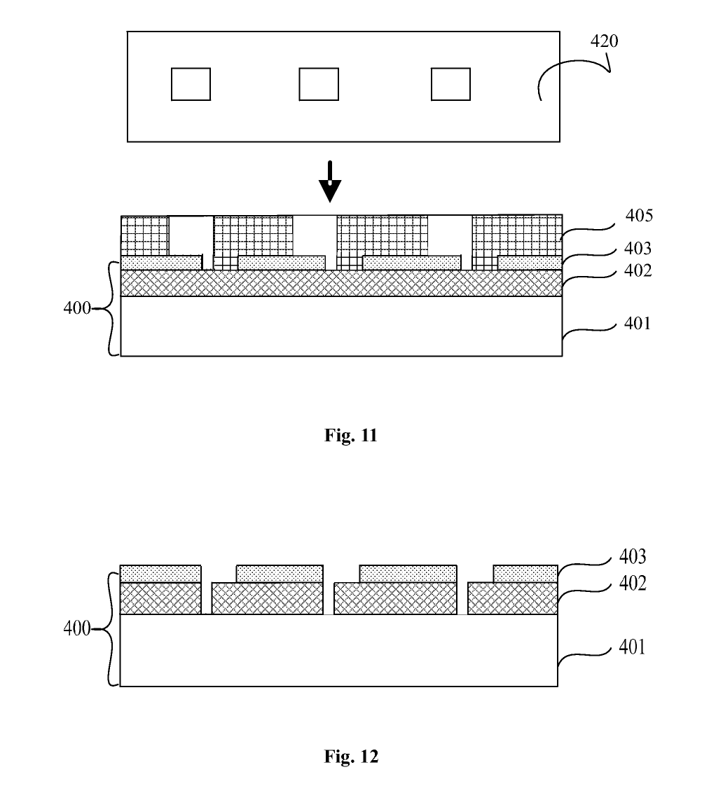

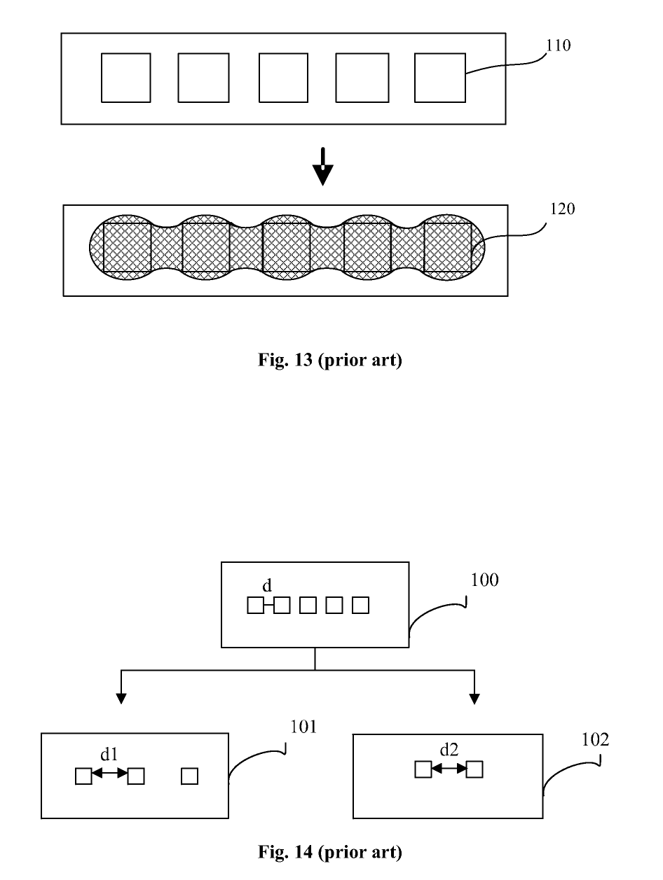

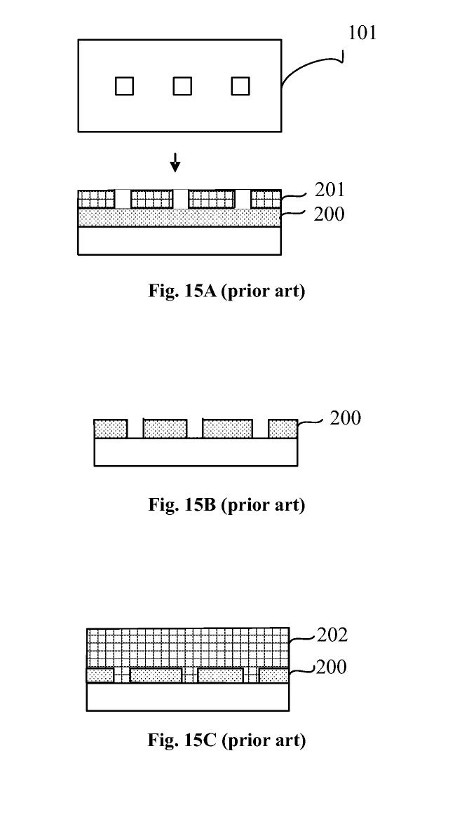

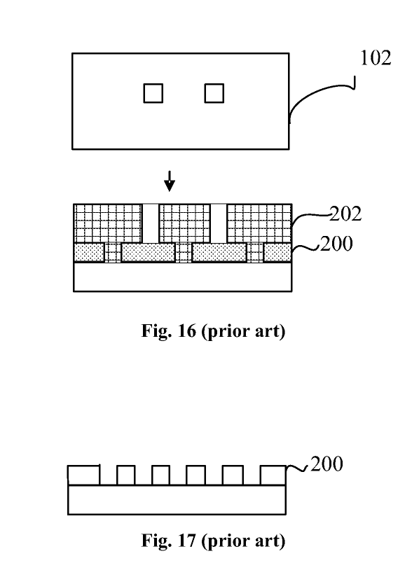

Referring to FIG. 11, the second patterns of the second mask 420 are transferred to the second photoresist layer 405 by exposure and development. The etch layer 402 has a part exposed to exterior, which is designated as a second exposed part. The second exposed part corresponds to the overlap area which is formed when the first patterns of the first mask 410 and the second patterns of the second mask 420 are projected on a common surface and are overlapped to each other. The overlap area defines the layout patterns of the layout topography, and correspondingly, the second exposed part of the etch layer 402 forms the layout patterns of the layout topography.

Referring to FIG. 12, the second exposed part of the etch layer 402 is etched according to the second photoresist layer 405 and the hard mask layer 403 by plasma dry etching process. The gas for etching is non-reactive with the hard mask layer 403. The gas for etching, etching process, and etching process parameters may be varied in terms of practical requirements of the ordinary skill in the art, and are not subject to limitation of the description herein.

The step S4 further comprises a step of removing the second photoresist layer and the hard mask layer after the step S43.

According to the photolithography method of the present invention, the layout patterns of a layout topography having critical dimensions unreadable to existing photolithography machines can be retrieved on the wafer under existing process conditions. Replacement of the existing photolithography machines is avoided. As a result, cost is reduced and yield rate is elevated.

The present invention has been described in conjunction with the preferred embodiments which, however, do not limit the invention. Various modifications and supplements may be made to the preferred embodiments by the ordinary skill in the art without departing from the spirit and scope of invention as set forth in the appended claims.

What is claimed is:

1. A photolithography method comprising:
arranging a layout topography in a first mask and a second mask in such a way that at least a layout pattern of the layout topography is defined by an overlap area, the overlap area being formed when at least a first pattern of the first mask and at least a second pattern of the second mask are projected on a common surface and are overlapped to each other;
providing a wafer which includes at least an etch layer and at least a hard mask layer on the etch layer;
transferring the at least a first pattern of the first mask to the hard mask layer; and
forming a second photoresist layer on the hard mask layer and the etch layer, transferring the at least a second pattern of the second mask to the second photoresist layer, and transferring the overlap area to the etch layer according to the hard mask layer and the second photoresist layer for forming the at least a layout pattern of the layout topography on the etch layer.

2. The photolithography method as claimed in claim 1, wherein critical dimensions of the first mask are larger than a resolution of a photolithography machine.

3. The photolithography method as claimed in claim 2, wherein the critical dimensions of the first mask comprise critical dimensions of the at least first patterns.

4. The photolithography method as claimed in claim 1, wherein critical dimensions of the second mask are larger than the resolution of the photolithography machine.

5. The photolithography method as claimed in claim 4, wherein the critical dimensions of the second mask comprise critical dimensions of the at least second patterns.

6. The photolithography method as claimed in claim 1, wherein the step of providing a wafer comprises:
providing a substrate;
forming an etch layer on the substrate; and
forming a hard mask layer on the etch layer.

7. The photolithography method as claimed in claim 1, wherein the step of transferring the at least a first pattern of the first mask to the hard mask layer, comprises:
forming a first photoresist layer on the hard mask layer of the wafer;
transferring the at least a first pattern of the first mask to the first photoresist layer by exposure and development;
transferring the at least a first pattern to the hard mask layer according to the first photoresist layer by etching; and
removing the first photoresist layer.

8. The photolithography method as claimed in claim 1, wherein in the step of transferring the at least a first pattern of the first mask to the hard mask layer, gas used for etching is a mixture of Trifluoromethane and Argon with volume ratio of 1:3 to 1:0.3.

9. The photolithography method as claimed in claim 1, wherein the first photoresist layer and the second photoresist layer are respectively formed of positive photoresist.

10. The photolithography method as claimed in claim 9, wherein in the step of transferring the at least a first pattern of the first mask to the hard mask layer, a part of the first photoresist layer is exposed to form a first exposed part corresponding to the at least a first pattern of the first mask.

11. The photolithography method as claimed in claim 9, wherein in the step of transferring the overlap area to the etch layer, a part of the etch layer is exposed to form a second exposed part corresponding to the overlap area.

12. The photolithography method as claimed in claim 1, wherein the step of transferring the overlap area to the etch layer comprises etching the etch layer according to the second photoresist layer and the hard mask layer, gas used for etching being non-reactive with the hard mask layer.

13. A photolithography method comprising: arranging a layout topography in a first mask and a second mask in such a way that at least a layout pattern of the layout topography is defined by an overlap area, the overlap area being formed when at least a first pattern of the first mask and at least a second pattern of the second mask are projected on a common surface and are overlapped to each other, wherein critical dimensions of the first mask and the second mask are larger than a resolution of a photolithography machine.

14. The photolithography method as claimed in claim 13, wherein the critical dimensions of the first mask comprise critical dimensions of the at least first patterns.

15. The photolithography method as claimed in claim 13, wherein the critical dimensions of the second mask comprise critical dimensions of the at least second patterns.

16. The photolithography method as claimed in claim 13, further comprising: providing a wafer which includes at least an etch layer and at least a hard mask layer on the etch layer, and transferring the at least a first pattern of the first mask to a hard mask layer of a wafer.

17. The photolithography method as claimed in claim 16, further comprising:
forming a second photoresist layer on the hard mask layer and the etch layer, transferring the at least a second pattern of the second mask to the second photoresist layer, and transferring the overlap area to the etch layer according to the hard mask layer and the second photoresist layer for forming the at least a layout pattern of the layout topography on the etch layer.

18. A photolithography method comprising:
arranging a layout topography in a first mask and a second mask in such a way that at least a layout pattern of the layout topography is defined by an overlap area, the overlap area being formed when at least a first pattern of the first mask and at least a second pattern of the second mask are projected on a common surface and are overlapped to each other;
providing a wafer which includes at least an etch layer and at least a hard mask layer on the etch layer;
transferring the at least a first pattern of the first mask to the hard mask layer, the hard mask layer forming a first exposed part corresponding to the at least a first pattern; and
forming a second photoresist layer on the hard mask layer and the etch layer, transferring the at least a second pattern of the second mask to the second photoresist layer, and transferring the overlap area to the etch layer according to the hard mask layer and the second photoresist layer to form at least a layout pattern of the layout topography on the etch layer, wherein the etch layer forms a second exposed part corresponding to the at least a layout pattern.

19. The photolithography method as claimed in claim 18, wherein critical dimensions of the first mask and the second mask are larger than a resolution of a photolithography machine.

20. The photolithography method as claimed in claim 19, wherein the critical dimensions of the first mask comprise critical dimensions of the at least first patterns, and wherein the critical dimensions of the second mask comprise critical dimensions of the at least second patterns.
